(19) United States
(12) Patent Application Publication
(10) Pub. No.: US 2026/0189031 A1
(43) Pub. Date: Jul. 2, 2026

(54) METHOD FOR ENTERING BALANCING AND STATE OF CHARGE CALIBRATING STATE AUTOMATICALLY

(71) Applicant: FLUENCE ENERGY, LLC, Arlington, VA (US)

(72) Inventors: Thomas Jeffrey Winter, Decatur, GA (US); Brett Lance Galura, Vienna, VA (US)

(73) Assignee: FLUENCE ENERGY, LLC, Arlington, VA (US)

(21) Appl. No.: 18/867,948

(22) PCT Filed: Sep. 27, 2024
(86) PCT No.: PCT/US2024/048756

§ 371 Date: Nov. 21, 2024

Related U.S. Application Data
(60) Provisional application No. 63/541,136, filed on Sep. 28, 2023.

(51) Int. Cl. H02J 7/52; H01M 10/42; H01M 10/48; H01M 50/251; H02J 3/32; H02J 7/82

(52) U.S. Cl. CPC H02J 7/52; H01M 10/425; H01M 10/482; H01M 50/251; H02J 3/32; H02J 7/82; H01M 2010/4271; H01M 2220/10

(57) ABSTRACT

A system includes a plurality of energy storage nodes and a control system to measure and record data of at least one component of interest within the system and determine an implementation of at least one of a battery balancing or calibration protocol of the control system for the component of interest. The implementation of the protocol is based on a predetermined value of at least one of measured raw data, a time interval, or an amount of energy throughput for the component of interest. When a determination for a calibration or balancing is made, an operation state of the component of interest is switched to a state to implement the calibration or balancing, respectively, and the state of charge is calibrated to a desired level or balanced to a desired state for the component of interest.

### CROSS-REFERENCE TO RELATED APPLICATIONS

This application claims priority under 35 U.S.C. § 120 to U.S. Patent Application Ser. No. 63/541,136 filed on Sep. 28, 2023, titled “Method for Entering Balancing and State of Charge Calibrating State Automatically,” the entire disclosure of which is incorporated by reference herein.

### TECHNICAL FIELD

The present subject matter relates to examples of a self-calibrating, self-balancing energy storage system design, and embedded methods of analysis for a battery in an energy storage system, wherein the energy storage system enters a balancing or state of charge calibrating state automatically within operating constraints of an energy system operation.

### BACKGROUND

Battery energy storage systems, compound energy storage systems, as well as energy provisioning systems over time and through use, will go out of balance, and have their state of charge (SoC) become miscalibrated. A battery with a calibrated SoC will accurately represent as an output signal the amount of energy remaining in the battery (e.g., outputting “50%” when a 100-kW battery is capable of outputting another 50 kW before being fully discharged.) An uncalibrated SoC will be inaccurate in representing the amount of energy remaining in the battery. In particular, SoC tends to become miscalibrated on the tails of the SoC chart first, meaning that while reporting “50%” can mean the battery retains 50% of its energy, reporting 10% can mean the battery retains 3% of its energy. This is problematic for several reasons. The overall system cannot accurately report the amount of energy it is capable of provisioning. If underreporting remaining discharge capacity, energy gets “trapped” in the battery, unable to be used and is essentially wasted. If underreporting remaining charge capacity, the battery can be undercharged below its maximum true capacity, wasting that portion of the battery's potential storage. If overreporting remaining discharge capacity, the battery can be over drained, which can cause damage to the battery (particularly acid-based batteries). If overreporting remaining charge capacity, the battery can be overcharged and potentially experience a catastrophic failure.

Additionally, while individual batteries require accurate SoC readings, the entire energy storage system also needs to be balanced. A balanced system has all of its constituent batteries at the same or very similar SoC. An unbalanced system has constituent batteries at various states of SoC. Even if the SoC values for the batteries are accurate, in an unbalanced system the batteries can only charge as high as the lowest charging battery, and can only discharge as low as the highest discharging battery. Therefore, the energy storage system (or a networked subset of components in the energy storage system) is limited by its one or two most out of balance batteries. Given that within a given battery node there are hundreds or even thousands of individual battery cells, and the performance of the battery node can be limited in the same way by its one or two most out of balance cells, in some cases an entire megawatt battery array can have its overall power capacity limited by a single multi-watt battery cell.

However, contemporary energy storage systems do not automatically take themselves into states where calibration or SoC balancing occur. Rather, these states are entered as they happen to occur—such as when a battery or battery array coincidentally fully charges or discharges. Therefore, there is no guarantee a battery will be calibrated or balanced when the battery or storage system would materially benefit it.

As previously indicated, in order to remain in balance and calibrated, battery systems must periodically be balanced and calibrated to report an accurate state of charge as well as to maximize the amount of energy that can be charged and discharged from the battery. However, these routines can only be entered under certain conditions, driven by the characteristics of the batteries and the measurements available to the battery management system. For example, a BMS may only enter balancing when the current to or from a battery it manages is very close to zero. Or, a BMS may only enter SoC calibration when the resting voltage of a battery it manages is in certain states, such as near top of charge or near bottom of charge.

There has not been an attempt to shape overall system operation to promote and trigger or facilitate conditions under which the battery system will undergo such balancing and calibration routines. Rather, these routines only occur when conditions coincidentally happen to align.

### SUMMARY

Hence, there in a need for systems and methods directed to placing an energy storage system into a balancing state, and batteries into a calibration state, based on the needs of the energy storage system. The energy storage automated balancing and calibration technologies disclosed herein determine whether balancing or state of charge calibration is needed, at an individual battery, node, core, or array level. Once determined, the energy storage automated balancing and calibration technologies intentionally takes the respective battery, node, core, or array to a state which facilitates balancing or calibration, for example by bleeding off or provisioning to a load or grid additional energy, thereby fully depleting the battery, node, core, or array. Additionally, in systems with multiple nodes, cores, or arrays, the energy storage automated balancing and calibration technologies selectively calibrate or balance specific or predetermined nodes, cores, or array in order to minimally impact the overall power provisioning capabilities of the entire energy storage system.

By controlling when energy storage systems enter calibration or balancing modes, the energy storage automated balancing and calibration technologies provide a benefit of reducing the amount of misbalance, as well as improving the accuracy of the remaining energy reported. In this way, the amount of usable energy from the energy storage system is increased and the control of the system based on remaining energy is improved (resulting in, for example, fewer equipment faults, or improved reporting to operations teams).

In a first example, an energy storage system 100 includes a plurality of energy storage nodes 110A-N and a control system 105. Each of the plurality of energy storage nodes 110A-N includes a plurality of battery modules 412A-N. The control system 105 includes at least one processor coupled to the plurality of energy storage nodes 110A-N and a memory configured to receive or store data and programming. The at least one processor of the control system 105 is configured to perform operations in accordance with execution of the programming, and measure and record operational and environmental data of at least one component of interest within the energy storage system 100. The processor is further configured to determine an implementation of at least one of a battery balancing or calibration protocol 500 based upon an analysis of the measured raw data 599. The implementation of the at least one battery balancing or calibration protocol 500 is based on a predetermined value of at least one of the measured raw data 599, a time interval, or an amount of energy throughput for the component of interest. In the determination for the implementation of the battery balancing or calibration protocol 500, the processor is further configured to compare a previously acquired value for a state of charge for the component of interest to values derived from at least one of the measured raw data 599, the time interval, or the amount of energy throughput to provide a calibration determination for a state of charge calibration. When the calibration determination is a predetermined value, an operation state of the component of interest is switched to a state to implement a calibration, and the state of charge is calibrated to a desired level for the component of interest. The processor is further configured to compare the previously acquired value of the state of charge for a sub-component of the component of interest to values derived from at least one of the measured raw data, the time interval, or the amount of energy throughput to provide a balancing determination for a state of charge balancing. When the balancing determination is a predetermined value, an operation state of the component of interest is switched to a state to implement a balancing, and the state of charge is balanced to a desired state.

In a second example, a method includes measuring and recording operational and environmental data of at least one component of interest within an energy storage system 100 to provide raw data 599. The method further includes determining an implementation of at least one of a battery balancing or calibration protocol 500 of a processor in a control system 105 for at least one component of interest based upon an analysis of the measured raw data 599. The implementation of the at least one battery balancing or calibration protocol 500 is based on a predetermined value of at least one of the measured raw data 599, a time interval, or an amount of energy throughput for the component of interest. In the determination for the implementation of the battery balancing or calibration protocol 500, the processor is further configured to compare a previously acquired value for a state of charge for the component of interest to values derived from at least one of the measured raw data 599, the time interval, or the amount of energy throughput to provide a calibration determination for a state of charge calibration. When the calibration determination is a predetermined value, the processor is further configured to switch an operation state of the component of interest to a state to implement a calibration, and the state of charge is calibrated to a desired level for the component of interest. The method further includes comparing the previously acquired value of the state of charge for a sub-component of the component of interest to values derived from at least one of the measured raw data, the time interval, or the amount of energy throughput to provide a balancing determination for a state of charge balancing. When the balancing determination is a predetermined value, the processor is further configured to switch an operation state of the component of interest to a state to implement a balancing, and the state of charge is balanced to a desired state. When the calibration determination is a predetermined value, an operation of the component of interest is switched to a state to implement a calibration, and the state of charge is calibrated to a desired level for the component of interest. The processor is further configured to compare the previously acquired value of the state of charge for a sub-component of the component of interest to values derived from at least one of the measured raw data, the time interval, or the amount of energy throughput to provide a balancing determination for a state of charge balancing. When the balancing determination is a predetermined value, an operation of the component of interest is switched to a state to implement a balancing, and the state of charge is balanced to a desired state

In a third example, a non-transitory computer readable medium 613, 652 includes a battery balancing and calibration module 500. Execution of the battery balancing and calibration module 500 by one or more processors 612, 652 configures one or more computing devices 105, 108 to measure 255 and record operational and environmental data to provide raw data 599. The one or more processor 612, 652 are further configured to determine an implementation of at least one of a battery balancing or calibration module of a control system 105, 108 for at least one component of interest within an energy storage system 100. The implementation of the battery balancing or calibration module by the processor 612, 652 is based on a predetermined value of at least one of the measured raw data, a time interval, or an amount of energy throughput for the component of interest. In the determination implementation of the battery balancing or calibration module, the processor 612, 652 is further configured to compare a previously acquired value for a state of charge 109A-N for a component of interest to values derived from at least one of the measured raw data, the time interval, or the amount of energy throughput to provide a calibration for a state of charge calibration. When the calibration determination is a predetermined value, an operation state of the component of interest is switched to a state to implement a calibration, and the state of charge is calibrated to a desired level for the component of interest. The processor 612, 652 is further configured to compare the previously acquired value of the state of charge 109A-N for a sub-component of the component of interest to values derived from at least one of the measured raw data, the time interval, or the amount of energy throughput to provide a balancing determination for a state of charge balancing. When the balancing determination is a predetermined value, an operation state of the component of interest is switched to a state to implement a balancing, and the state of charge is balanced to a desired state.

Additional objects, advantages and novel features of the examples will be set forth in part in the description which follows, and in part will become apparent to those skilled in the art upon examination of the following and the accompanying drawings or may be learned by production or operation of the examples. The objects and advantages of the present subject matter may be realized and attained by means of the methodologies, instrumentalities and combinations particularly pointed out in the appended claims.

### BRIEF DESCRIPTION OF THE DRAWINGS

The drawing figures depict one or more implementations in accordance with the present concepts, by way of example only, not by way of limitations. In the figures, like reference numerals refer to the same or similar elements.

FIG. 1A is an isometric view of a battery energy storage system that includes multiple energy storage nodes, a central control system element, and an external grid.

FIG. 1B is an isometric view of a single energy storage node, multiple optional energy storage nodes, and an external grid.

FIG. 2 is an electrical diagram of a battery energy storage system similar to that of FIGS. 1A-B depicting information and working power flows.

FIG. 3 is a system diagram of a battery energy storage system similar to that of FIGS. 1A-B depicting step-up converter controllers and the distributed nature of a battery energy storage system.

FIG. 4 is an isometric translucent view of the energy storage node of FIG. 1B that includes a battery bank of multiple battery modules.

FIG. 5 is a flowchart of the battery balancing and calibration protocol.

FIG. 6 is a high-level functional block diagram of the energy storage system of FIGS. 1A and 1B that depicts components of the control system and the energy storage system nodes to control power flow, overall operations and implementation of a battery balancing and calibration protocol.

### PARTS LISTING

100 Battery Energy Storage System
102 Energy Source
104 Power Conversion System (PCS)
105 Central Control System Element
106 Connected Load
108 Control Subsystem
109A-N Battery Data
110A-N Energy Storage Nodes
111 Energy Storage Element
112 Required Power Flow
113 External Grid
114A-C Distributed PCS
115 Overall Operations
116A-O Battery Conditions
150 Battery Array
155A-C Battery Core
200 Battery Energy Storage System
211 Core Controller
212 Power Plant Controller
251 High Voltage (HV) Bus
252 Medium Voltage (MV) Bus
254 Point of Connection (POC)
255 Data Collection Sensors
256A-N Meter Readings
257 HV/MV Transformer
258A-X Core Transformer
259A-X Core
260A-X MV Circuit Breaker (CB_Core)
261 HV Circuit Breaker (CB_HV)
262 Array
410A-F Battery Strings
412A-N Battery Modules
413 Battery Bank
500 Battery Balancing and Calibration Protocol
605 Network
610 Physical Space
611 Network Communication Interface
612 Processor
613 Memory
616A-N Battery Conditions
651 Network Communication Interface
652 Processor
653 Memory
BMS Battery Management System
APS Apparent Power System Controller
Node SDU Node Storage Dispatch Unit
MDU Market Dispatch Unit
RTAC Real Time Automation Controller

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, transfer functions, and/or circuitry have been described at a relatively high-level, without detail, in order to avoid unnecessarily obscuring aspects of the present teachings.

The term “coupled” as used herein refers to any logical, physical, electrical, or optical connection, link or the like by which electricity, power, signals or light produced or supplied by one system element are imparted to another coupled element. Unless described otherwise, coupled elements or devices are not necessarily directly connected to one another and may be separated by intermediate components, elements, or communication media that may modify, manipulate, or carry the electricity, power, light or signals.

Unless otherwise stated, any and all measurements, values, ratings, positions, magnitudes, sizes, angles, and other specifications that are set forth in this specification, including in the claims that follow, are approximate, not exact. Such amounts are intended to have a reasonable range that is consistent with the functions to which they relate and with what is customary in the art to which they pertain. For example, unless expressly stated otherwise, a parameter value or the like may vary by as much as ±5% or as much as ±10% from the stated amount. The terms “approximately,” “significantly,” or “substantially” means that the parameter value or the like varies up to ±25% from the stated amount.

The orientations of the battery nodes, cores, arrays, racks, elements, modules, submodules, strings, banks, or cells; associated components; circuits; and/or any complete devices, such as battery energy storage systems, combined energy storage systems, or modular energy storage systems, incorporating battery nodes, racks, elements, modules, submodules, strings, banks, or cells such as shown in any of the drawings, are given by way of example only, for illustration and discussion purposes. In operation for a particular battery energy storage application, a battery node, core, array, rack, element, module, submodule, string, bank, or cell may be oriented in any other direction suitable to the particular application of the battery energy storage system, for example upright, sideways, or any other orientation. Also, to the extent used herein, any directional term, such as left, right, front, rear, back, end, up, down, upper, lower, top, bottom, and side, are used by way of example only, and are not limiting as to direction or orientation of any energy storage system or battery nodes, racks, elements, modules, submodules, strings, banks, or cells; or component of an energy storage system or battery node, rack, element, module, submodule, string, bank, or cell examples illustrated in the accompanying drawings and discussed below.

Unless otherwise indicated, any multiplicity of components, such as energy storage nodes 110A-N, battery strings 410A-F, or battery modules 412A-N can include any number of said components, including as few as one, and are not limited by the depicted number of components. Unless otherwise indicated, any coupled electrical components can be linked in series or in parallel. In the case of energy storage nodes 110A-N or battery modules 412A-N, the component may be linked in both series and/or in parallel, depending upon the state of the switch or submodule.

Reference now is made in detail to the examples illustrated in the accompanying drawings and disclosed below.

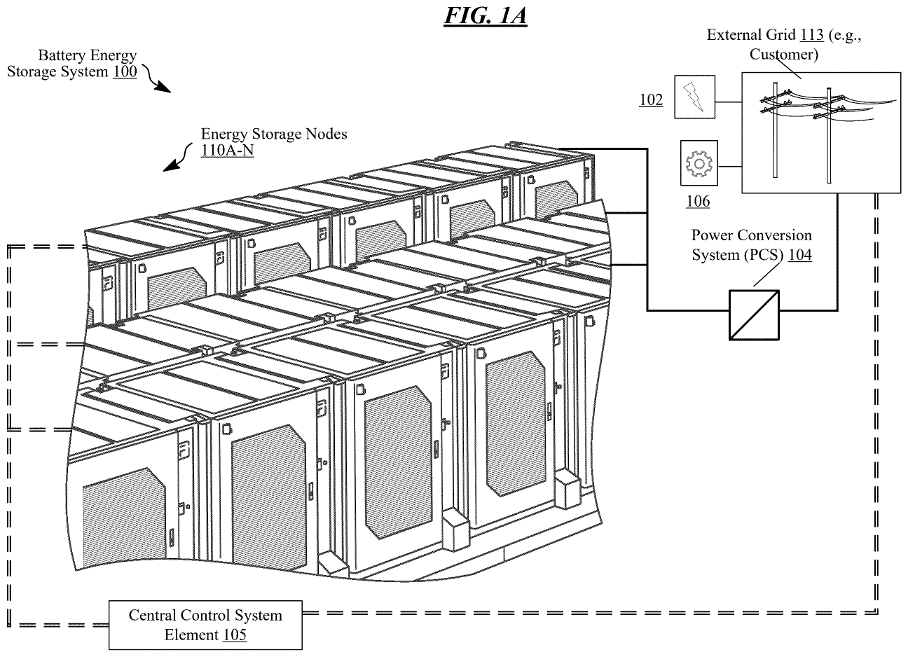

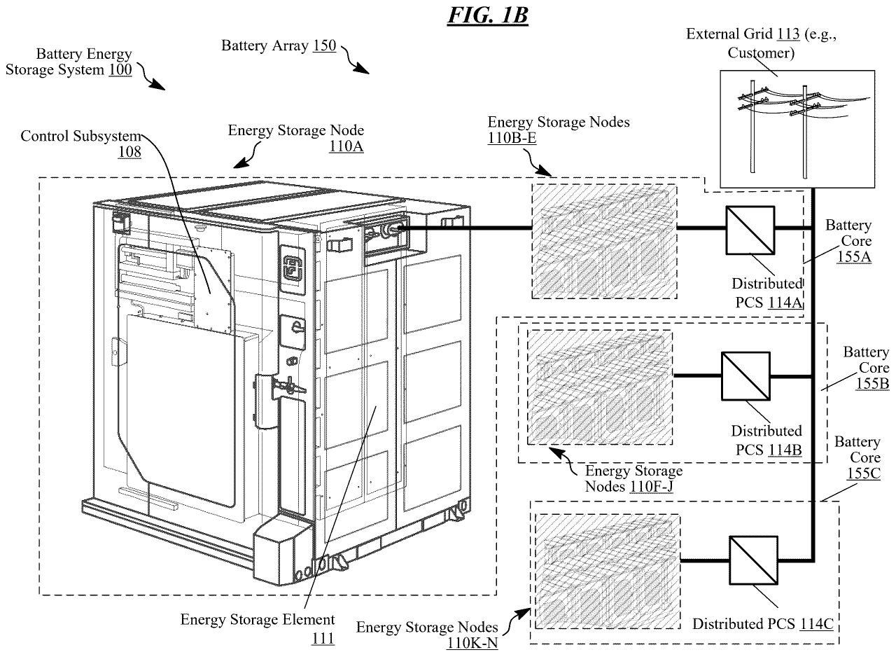

FIG. 1A is an isometric view of an energy storage system, for example, a battery energy storage system (“BESS”) 100 that includes multiple energy storage nodes 110A-N, a central control system element 105, and an external grid 113. The battery energy storage system 100 includes multiple energy storage nodes 110A-N optionally connected to a power conversion system (PCS) 104. The energy storage nodes 110A-N include batteries of any existing or future reusable battery technology including, for example, lithium ion, flow batteries, or mechanical storage such as flywheel energy storage, compressed air energy storage, pumped storage hydroelectricity, gravitational potential energy, or a hydraulic accumulator. The energy storage nodes 110A-N, collectively and individually, are capable of providing direct current electricity to an external load, for example, connected load 106, and thereby discharging, as well as are capable of receiving direct current electricity from an external source, for example, energy storage 102, and thereby charging.

The energy source 102 can be part of any suitable system for producing electrical energy. In an example, the system can be a renewable energy system in which the energy source 102 can be replenished. Such a renewable energy source 102 can include solar power, wind power, geothermal power, biomass, and hydroelectric power. For example, the renewable energy system can be implemented as an array of photovoltaic modules. The photovoltaic (PC) modules can include crystalline silicon, amorphous silicon, copper indium gallium selenide (CIGS) thin film, cadmium telluride (CdTe) thin film, and concentrating photovoltaic which uses lenses and curved mirrors to focus sunlight onto small, but highly efficient, multi-junction solar cells. In another example, the energy system for the energy source 102 can be a non-renewable energy system in which the energy source 102 includes a non-renewable energy source, such as a fossil fuel.

To facilitate providing and receiving direct current, the energy storage nodes 110A-N can be connected to the power conversion element 104. The power conversion system 104 is configured to standardize power inputs and outputs to and from the energy storage nodes 110A-N. The power conversion system 104 can be comprised of: (1) an inverter, converting the DC source of the energy storage nodes 110A-N to an AC waveform, and vice versa; (2) a DC/DC converter, converting the DC source of the energy storage nodes 110A-N to a different DC source characteristic; (3) other known power conversion elements; or (4) a combination thereof.

When the energy storage nodes 110A-N provide direct current, the power conversion system 104 transforms the direct current into alternating current for use by the external grid 113 and normalizes the amperage from the battery modules (not pictured) of the energy storage nodes 110A-N to the external grid 113. Additionally, when the energy storage nodes 110A-N require direct current, the power conversion system 104 transforms alternating current into direct current from the external grid 113 and normalizes the amperage from the external grid 113 to the energy storage nodes 110A-N. As shown in FIG. 1B, the energy storage nodes 110A-N may be coupled in groups to a distributed power conversion system 114A-114C, which may perform some or all of the tasks of the power conversion system 104 and may obviate entirely the use of a power conversion system 104.

The battery energy storage system 100 including the energy storage nodes 110A-N (and the power conversion system 104 and when the central power conversion system 104 is not omitted) is depicted with a single connection to the external grid Ingrid 113. In scenarios where the external grid 113 is complex and connects to multiple energy sources 102 and connected loads 106, such as a power grid with consumption devices, a single connection to the battery energy storage system 100 can either absorb energy produced by the energy sources of the external grid 113 in excess of the demand of the connected loads of the external grid 113, or provide energy to the connected loads of the external grid 113 in excess of the capacity of the energy sources of the external grid 113. Alternatively, separate lines may run to a segregated energy source as well as to connected loads or the external grid 113. Separate lines may be advantageous in scenarios where the segregated energy source is inconsistent, such as a wind or solar-based energy source. In such scenarios, the power from the energy source is pushed to the energy storage modules 110A-N, which then either charge or discharge, and provide consistent energy to the connected loads or external grid 113 via another electrical route.

An energy source 102 can be any suitable system for producing electrical energy, such as a turbine or photovoltaic cell. The external grid 113 can include a power grid or a smaller local load such as a backup power system for a facility such as a hospital, manufacturing site, residential home, or other suitable facility.

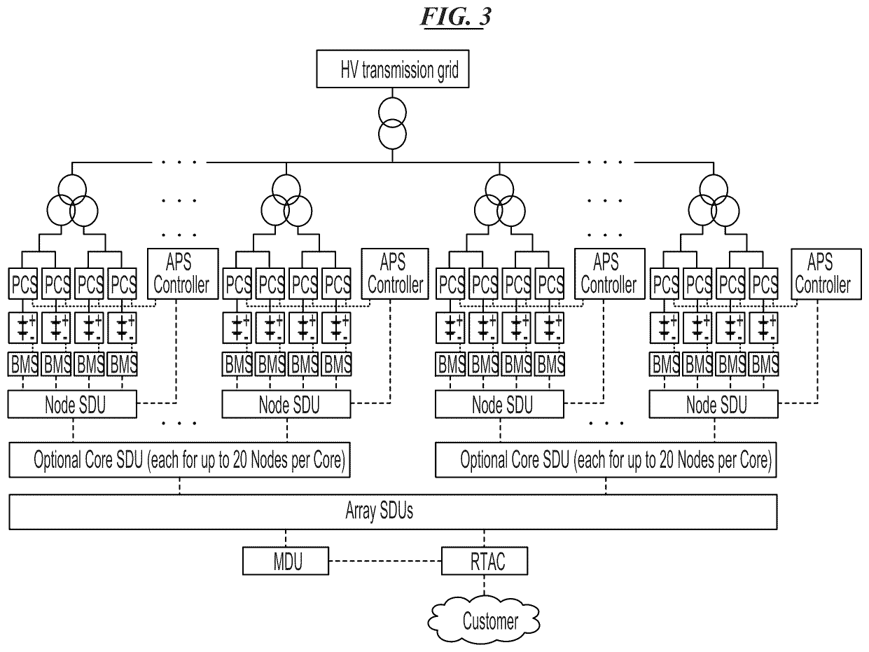

The power conversion system 104 can facilitate normalizing input or output wattage or voltage, in order to provide consistent output and protect the energy storage nodes 110A-N or external grid 113 from damage. The power conversion system 104 may perform this normalization in concert with a central control system element 105 including at least one processor. The central control system element 105 also communicates with and controls the energy storage nodes 110A-N in order to adjust electrical output, as well as electrical capacity or intake of the energy storage nodes 110A-N. The central control system element 105 has components, such as those depicted in FIG. 3 which operate independently at their respective levels. Therefore, the central control system element 105 and the distributed control system elements (e.g., BMSs, APS controllers, SDUs, MDUs, and RTAC (see FIG. 3)) are configured to operate in a combination of independent and centralized operation.

Generally, the energy storage nodes 110A-N of the battery energy storage system 100 connected to the external grid 113 operate in concert: either providing power to the external grid 113 and discharging or receiving power from the external grid 113 and charging. This concerted effort is coordinated by central control system element 105, and other control units such as market dispatch units (MDUs) or real-time automation controllers (RTACs), depicted in FIG. 3. Further methods and systems related to the management and maintenance of the energy storage nodes 110A-N (e.g., battery modules 412A-N) of the battery energy storage system 100 are disclosed in U.S. application Ser. No. 17/810,983, filed on Jul. 6, 2022, now U.S. Pat. No. 11,789,086, issued Sep. 27, 2023, titled “Cell and Rack Performance Monitoring System and Method,” the entirety of which is incorporated by reference herein.

FIG. 1B is an isometric view of an energy storage node 110A, multiple optional energy storage nodes 110B-N, and an external grid 113. The energy storage node 110A includes an energy storage element 111.

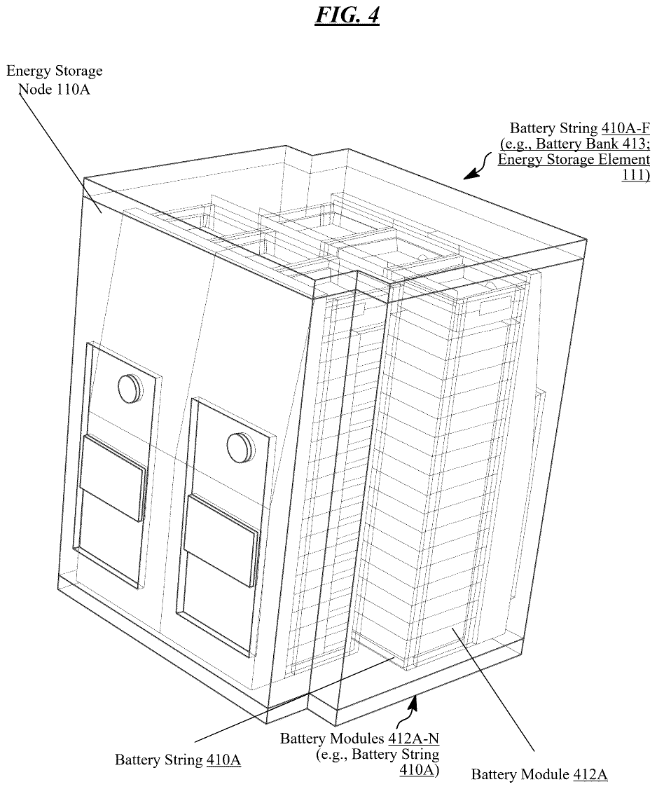

The energy storage element 111 can include: (1) a single battery cell; (2) a cell grouping, including several battery cells in parallel configuration; (2) a battery submodule or module 412A (see FIG. 4), including several battery cells in parallel and serial configuration; (4) a battery string 410A (see FIG. 4), including several battery modules 412A-N in series; (5) a battery bank 413 (see FIG. 4), including several battery strings 410A-F in parallel; (6) other known energy storage elements; or (7) a combination thereof.

The energy storage node 110A can include, for example, HVAC heating or cooling elements to regulate the temperature of the energy storage node 110A, in particular the energy storage element 111.

The energy storage nodes 110A-N are organized into collections of nodes 110A-E, 110F-J, 110K-N, each collection paired with a distributed power conversion system 114A-C. A grouping of nodes 110A-E with a distributed power conversion system 114A constitutes a battery core 155A.

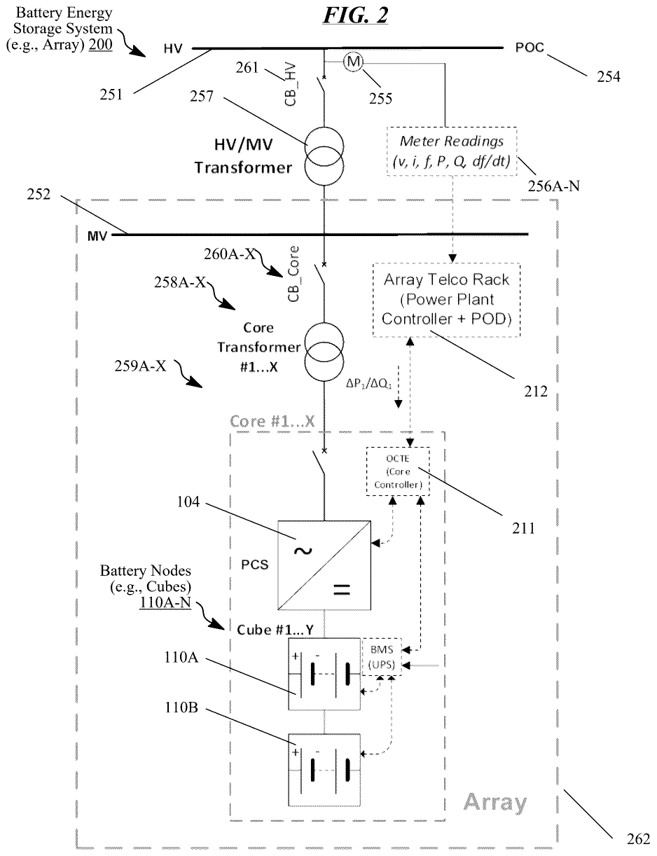

The distributed power conversion system 114A-C can include: (1) an inverter, converting the DC source of the energy storage element 111 to an AC waveform, and vice versa; (2) a DC/DC converter, converting the DC source of the energy storage element 210 to a different DC source characteristic; (3) other known power conversion elements; or (4) a combination thereof. The distributed power conversion systems 114A-C can service an individual energy storage node 110A, or any number of energy storage nodes 110A-N. Multiple energy storage nodes 110A-N are generally arranged in series, although other wiring sequences are contemplated. A distributed power conversion system 114A servicing multiple energy storage nodes 110A-E can be a battery core 155A, and can be controlled by a core controller 212 (see FIG. 2). The core controller 212 can coordinate with a node controller present in each associated energy storage node 110A-E.

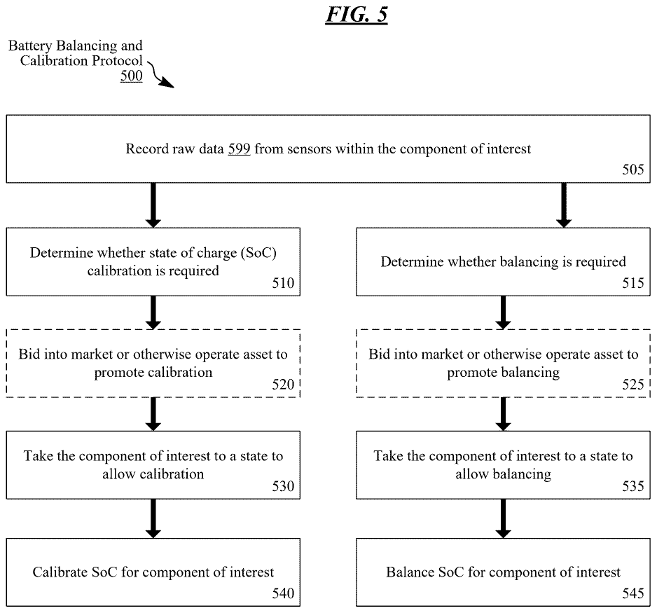

Physical data collection sensors and data logging can be used throughout the battery energy storage system 100, to collect operational and environmental data, in particular voltage, current, temperature, or state of charge from the components of the battery energy storage system, such as the energy storage node 110A, and the distributed PCSs 114A-C to produce raw data 599 (see FIG. 5).

FIG. 2 is an electrical diagram of a battery energy storage system 200 similar to the battery energy storage system 100 of FIG. 1 depicting information and working power flows.

The battery energy storage system 200 connects to an electrical grid, including both an energy source 102 and a connected load 106, via a point of connection (POC) 254. The POC 254 is coupled to a high voltage (HV) bus 251, which is an electrical bus rated and intended for high voltage matching the voltage expected by the electrical grid. The HV bus 251 can allow for multiple battery energy storage systems 200 or power storage or generating facilities to be linked in series or in parallel before connecting to an electrical grid via the POC 254.

The battery energy storage system 200 includes an HV circuit breaker 261, designed to selectively isolate the remainder of the battery energy storage system 200 from the HV bus 251. The HV circuit breaker 261 may be hardwired to trip under certain circumstances, or the HV circuit breaker 261 may be controlled by the power plant controller 212 or other controllers.

An HV/medium voltage (MV) transformer 257 is coupled between the HV bus 251 and an MV bus 252. The HV/MV transformer 257 steps the voltage experienced at the HV bus 251 connection down to the voltage expected at the MV bus 252 connection end, as well as stepping up the voltage from the MV bus 252 connection end to the voltage expected at the HV bus 251 connection end.

The MV bus 252 is within the bounds of the array 262. The array 262 includes a power plant controller 212 to facilitate operation of one or more cores 259A-X. While multiple arrays 262 may be coupled in series or in parallel to the MV bus 252, in this example only a single array 262 with a single power plant controller 212 is depicted.

A core 259A is coupled to the MV bus 252 by a core transformer 258A and a core circuit breaker 260A. Multiple cores 259A-X are connected to a single MV bus 252, each with a respective core transformer 259A-X and respective core circuit breaker 260A-X: in this figure, only a single core 259A is depicted in detail.

The MV circuit breaker 260A is designed to selectively isolate the remainder of the core 259A from the MV bus 252. The MV circuit breaker 260A may be hardwired to trip under certain circumstances, or the MV circuit breaker 260A may be controlled by the power plant controller 212, the core controller 211, or other controllers.

The core transformer 258A is coupled between the MV bus 252 and the core 259A. The core transformer 258A steps the voltage experienced at the MV bus 252 connection end down to the voltage expected at the core 259A connection end, as well as stepping up the voltage from the core 259A connection end to the voltage expected at the MV bus 252 connection end.

The core 259A includes the power conversion system 104, which includes all hardware and controls to convert bi-directionally between direct current (DC) and alternating current (AC) power. The power conversion system 104 provides AC power to and from the MV bus 252, and provides DC power to and from the cubes 110A-N.

At least one data collection sensor, for example, a meter 255 is connected near the HV bus 251 for the purpose of collecting at least measured values relevant to oscillation determinations: instant voltage, current, as well as power frequency, instant power, and the rate of change of frequency, are all values that can inform the power plant controller 212 and the POD controller 105 in dampening power oscillations.

The meter readings 256A-N are collected continuously or periodically by the meter 255 and are provided to the power plant controller 212.

Physical data collection sensors and data logging can be used throughout the battery energy storage system 200, to collect operational and environmental data, in particular voltage, current, temperature, or state of charge from the components of the battery energy storage system, such as the HV/MV transformers 257, core transformers 258A-X; cores 259A-X; buses 251, 252; meter 255, and controllers 212, 211 to produce raw data 599 that may be analyzed to derive values used in a determination for a balancing or calibration for a component of interest in the energy storage system.

FIG. 3 is a system diagram of a battery energy storage system similar to that of FIGS. 1A-B depicting step-up converter controllers and the distributed nature of a battery energy storage system. Energy storage nodes are electrically connected to power conversion systems (PCSs), which are then electrically connected together via a bus, then electrically connected via a three-winding transformer to another bus, which then electrically connects to the HV voltage grid via a transformer. The energy storage nodes are controlled by battery management systems (BMSs), which, along with the PCSs, communicate with apparent power system controllers (APSs). The APSs and the BMSs communicate with node storage dispatch units (SDUs). Node SDUs interface with and monitor the connected BMSs, PCSs and other hardware to higher level controls. The node SDUs communicate with core SDUs, which dispatch real and reactive power to the Nodes based on their operation conditions, as well as provide telemetry values to the node SDUs, and provide the array SDU and node SDUs with core-level system operation data. The core SDUs communicate with the array SDU, which provides a market dispatch unit (MDU) and real-time automation controller (RTAC) with measurements and system operation data. The array SDU also dispatches real and reactive power to the core SDUs based on core-level stored energy. The MDU executes real and reactive power applications, while the RTAC communicates with customer control systems utilizing adjustable various interfaces.

Physical data collection sensors and data logging can be used throughout the battery energy storage system, to collect operational and environmental data, in particular voltage, current, temperature, or state of charge from the components of the battery energy storage system, such as the energy storage nodes, PCSs, BMSs, APSs, node SDUs, core SDUs, array SDU, MDU, and RTAC, of the measured/observed operational and environmental data for at least one component of interest in the energy storage system to produce raw data 599 (see FIG. 5) that may be used to derive values related to a need for a calibration or balancing of a component of interest in the energy storage system.

FIG. 4 is an isometric translucent view of the energy storage node 110A of FIG. 1B that includes a battery bank 413 of multiple battery modules 412A-N. The energy storage node 110A stores a plurality of battery strings 410A-F as a battery bank 413 and as an energy storage element 111. The energy storage node 110A is both a physical housing of energy storage element 111, as well as a logical and electrical collection of the battery bank 413 that constitutes energy storage element 111: the energy storage node 110A physically houses the battery bank 413, and the electrical performance of the battery bank 413 comprising the energy storage element 111 may be attributed to the energy storage node 110A itself. For example, if a battery string 410A of the battery bank 413 is able to store one hundred and two kilowatt hours of energy, and the battery bank 413 contains six battery strings 410A-F, then the energy storage node 110A (as well as the energy storage element 111) may be understood to and be described as storing six hundred and twelve kilowatt hours of energy. An energy storage node 110A, energy storage element 111, and battery bank 413 may contain greater or fewer numbers of battery strings 410A-F than depicted in the figure.

A given battery string 410A contains multiple battery modules 412A-N. Much like the relationship between the energy storage node 110A and contained battery bank 413, the battery string 410A is both a physical collection of battery modules 412A-N as well as a logical and electrical collection of battery modules 412A-N. As an example, if a battery module 412A is able to store six kilowatt hours of energy, and the battery string 410A contains seventeen battery modules 412A-N, then the battery string 410A may be understood to and be described as storing one hundred and two kilowatt hours of energy. A battery string 410A may contain greater or fewer numbers of battery modules 412A than depicted in the figures.

As the battery string 410A is a logical and electrical collection of battery modules 412A-N, the collection is not necessarily defined by the physical structure or ordering of the battery modules 412A-N, other than the constituent battery modules 412A-N in this example are wired in series. Therefore, the battery string 410A may be alternatively described as a battery rack, a battery sub-rack, or a battery array: each of these terms (element, rack, sub-rack, array) can be categories of battery string 410A: a battery string 410A is the logical and electrical collection of battery modules 412A-N, without explicit regard for physical structure or ordering of the battery modules 412A-N, other than in this particular example wiring in series. In some implementations, a finer level of encapsulation exists within the battery module 412A, which may be identified as a battery grouping within the battery module 412. Those battery groupings may also include a finer level of encapsulation, which may be identified as a battery cell within the battery grouping, comprising prismatic, pouch, or cylindrical battery cells.

In this example, the energy storage node 110A represents a single physical fixture, which may be limited in maximum size by the mass or volume a person, forklift, or vehicle is capable of transporting as a singular, atomic unit. The battery bank 413 within the battery module 110A represents a physical organizational structure for organizing and wiring battery cells, groupings, battery modules 412A-N, and battery strings 410A-F within the energy storage node 110A. A battery cell is generally the largest unit of manufacture a battery producer can produce capable of charging and discharging electricity at a chemical level. In some examples battery cells are packaged together as battery modules 412A-N, representing the smallest unit a particular operator would remove or replace in the battery energy storage system 100: in examples where a multiple battery cells are packaged together, the individual battery cells are too small or sensitive to perform on-site particularized maintenance, and instead the entire package of battery cells (e.g., a battery module 412A) is either collectively repaired or replaced.

The energy storage nodes 110A may resemble the features presented in the energy storage system described in International Application No. PCT/US 2021/30551, filed on May 4, 2021 (published as WO 201226011 on Nov. 11, 2021), titled “Energy Storage System with Removable, Adjustable, and Lightweight Plenums,” the entirety of which is incorporated by reference herein.

Physical data collection sensors and data logging can be used throughout energy storage node 110A, to collect operational and environmental data, in particular voltage, current, temperature, or state of charge from the components of the energy storage node 110A, such as the battery cells, battery modules 412A-N, battery strings 410A-F, and battery bank 413 to produce raw data 599 (see FIG. 5) that may be used to derive values related to a need for a calibration or balancing of a component of interest in the energy storage system.

FIG. 5 is a flowchart of the battery balancing and calibration protocol 500. The battery balancing and calibration protocol 500 can be implemented across an entire battery energy storage system BESS 100, or on a subset of components, such as multiple energy storage nodes or a core 259A. When implemented across a component that includes multiple energy storage nodes 110A-N, calibration occurs either at the energy storage node 110A level or a lower level of abstraction (e.g., string 410A or module 412A), while balancing occurs at a higher level of abstraction (e.g., core, array, BESS 100). Calibration is preferably performed at the smallest level of abstraction (e.g., node 110A, string 410A, module 412A), in order to achieve the most accurate SoC levels for individual components, while balancing is preferably performed at largest level of abstraction (e.g., core 155A, array 262, BESS 100) in order to achieve the most components within balance of each other. The battery balancing and calibration protocol 500 can be implemented in a single device, represented by the central control system element 105, or in a distributed manner across the BMSs, SDUs, MDU and RTAC of FIG. 3.

The objective of balancing is to have all components in balance with each other such that all components and sub-components are at the same or approximately the same SoC at a given time. Thus, for example, given an Array A with Node B with modules C and D, and that Array A with Node E and modules F and G, Node B should be in balance with Node E, as well as the modules F and G of Node E—to be in balance with Node E, modules C and D of Node B would be in balance with Node E as well. Thus, in a balanceable system, each component and sub-component has an N-to-N balancing relationship with each and every other component and sub-component of the balanced system: the smallest module should be balanced with the largest array, as well as each and every other module, and every component or sub-component of each scale or level of abstraction. A single component or sub-component out of balance will make an entire BESS 100 out of balance.

Preferably, this can be achieved by balancing within a given level of abstraction, and then moving upwards: by balancing all of the modules in all strings, it becomes easier to balance all strings within all nodes, and consequently easier to balance all nodes within all cores. By balancing within a level of abstraction or scale or “fiefdom”, the balanced object can report a single SoC, or linear representation of SoC over a charging cycle, up to the next level of abstraction or scale. By doing so, a BESS 100 does not need to calculate for example ten million balancing strategies for ten million modules: the BESS 100 rather balances ten cores against one another. Then, within each single core of those ten cores, the core does not need to calculate one million balancing strategies for one million modules, the core rather balances fifty nodes against one another.

Because of the O(n²) time complexity of balancing relationships (due to the N-to-N relationships for balancing between components and sub components) it is quantitatively faster to balance at various levels of scope rather than simultaneously balancing all components against each other as a single operation. The time complexity utilizing this tiered strategy would result in an operational time complexity of O(m²), where m is the largest group of sub-components to be balanced for a given component. In a ten million module BESS 100, where the largest group of sub-components in a component is one thousand modules in one string, O(n²) results in an operation time of 100,000,000,000,000 (ten million squared), whereas the scaled strategy of O(m²) results in an operation time of 1,000,000 (one thousand squared)—a time performance improvement of one million to one.

The battery balancing and calibration protocol 500 operates on the theory that, rather than relying on luck or happenstance for the system to enter states which result in balancing or calibration, it is beneficial instead to intentionally place the BESS 100 or subcomponents of the BESS 100 into states which trigger or facilitate balancing or calibration, when the BESS 100 determines that such balancing or calibration would be beneficial.

In embodiments of the invention, the battery balancing and calibration protocol 500 first determines whether balancing is needed or whether state of charge calibration is needed. This can be done by decisioning based on voltage, current, temperature, and state of charge values (e.g., raw values 599) observed in the BESS 100. Or, this can be determined based on a certain time interval (i.e., once per week) or based on a certain amount of energy throughput (i.e., once every 1000 MWhs).

Once the BESS 100 determines that balancing and/or state of charge calibration is needed, the BESS 100 intentionally places itself into the condition where such actions occur, i.e., an operation state of the component of interest is switched to a state to implement the balancing and/or calibration. This could be, for example, going to a period of rest where self-balancing is known to occur, or to a low state of charge where state of charge calibration is known to occur.

While doing so, the operation of the remainder of the BESS 100 is adjusted to compensate for the portion of the system that is being specifically controlled. For example, in a BESS 100 with thirty Cores 259A-X, one Core 259A could be taken into a state where calibration or balancing is triggered, while the remaining twenty-nine Cores 259B-X perform the application on the grid 113. In another example, a BESS 100 could be bid into a market in a way that promotes balancing or calibration either as a whole or in parts as described in the first example.

To facilitate these principles, a control system such as the central control system element 105 comprises at least one processor that operates programming such as the battery balancing and calibration protocol 500 of FIG. 5 and performs the following operations. At block 505, the battery balancing and calibration protocol 500 records data including voltage, current, and state of charge (SoC) from components of interest (e.g., energy storage nodes 110A-N) within the BESS 100. These recorded data provide the raw data 599 that is used to derive values in the determination for balancing and/or calibration. Other datapoints relevant to determining balance or SoC may be collected and recorded.

A “component of interest” is any component which may be calibrated or balanced relative to itself. For example, an energy storage node 110A can be calibrated, meaning that the energy storage node 110A will provide an accurate SoC estimate for the energy storage node 110A—it may be possible that calibrating the energy storage node 110A does not calibrate all of the battery modules 412A-N within the energy storage node. The energy storage node 110A can also be balanced, meaning that within the energy storage node 110A the battery modules 412A-N will be in balance with one another—it may be possible that balancing the energy storage node 110A does not balance that energy storage node with the other energy storage nodes 110B-E in the same battery core 155A, or with other energy storage nodes 110B-N in the BESS 100.

Balancing and calibration can be related but are not necessarily synonymous. A miscalibrated energy storage node 110A may not be internally misbalanced—however the miscalibrated energy storage node 110A may be making its respective core 155A misbalanced. Calibration tends to be required on the components with lower levels of abstraction (e.g., energy storage node 110A, battery module 412A) while balancing tends to be required on components with higher levels of abstraction (e.g., core 155A, BESS 100). Balancing is most necessary between components which operate collectively, meaning components wired in series or parallel without selectable switches between the components. However, it may be desirable to balance components which do not operate collectively, such as the entire BESS 100.

Therefore, after block 505, the battery balancing and calibration protocol 500 splits into a calibration path and a balancing path. In block 510, the collected raw data 599 is analyzed and manipulated such that derivations may be used to determine whether a SoC calibration is required. This determination may be based on comparing a reported or previously obtain SoC for the component to derived valued of the voltage and/or current experienced/measured by the component.

If calibration is required, optionally at block 520, the battery balancing and calibration protocol 500 can bid or interact with the market or otherwise change an operation of the assets (BESS 100 and sub-components) to promote calibration. For example, if calibration requires fully discharging the battery, the battery balancing and calibration protocol 500 may aggressively bid to sell electricity, in order to ensure the battery can discharge to the external grid 113, rather than waste energy by bleeding it off. Similarly, if calibration requires fully charging the battery, the battery balancing and calibration protocol 500 may aggressively bid to buy electricity, in order to charge the battery in a relatively short period of time.

Next, in block 530, once SoC calibration is determined to be required, and optionally when it is market beneficial to calibrate, the battery balancing and calibration protocol 500 takes the component of interest to a state to permit calibration. This state could be, for example, full charge or full discharge.

Finally, in block 540, once the component of interest is in a state in which it can be calibrated, the battery balancing and calibration protocol 500 calibrates the SoC for the component of interest.

Simultaneous to a traversal of the calibrating path of blocks 510-540, the balancing path can be traversed. In block 515, derived values for the collected raw data 599 are used to determine whether balancing is required. This determination may be based on comparing the reported or previously obtained SoC for the sub-component of the component of interest to derived valued to determine whether there is substantial variability.

If balancing is required, optionally at block 525, the battery balancing and calibration protocol 500 can bid or interact with the market or otherwise change an operation of the assets to promote calibration. For example, if balancing requires fully discharging the batteries of the component of interest, the battery balancing and calibration protocol 500 may aggressively bid to sell electricity, in order to ensure the batteries can discharge to the external grid 113, rather than waste energy by bleeding it off. Similarly, if balancing requires fully charging the batteries, the battery balancing and calibration protocol 500 may aggressively bid to buy electricity, in order to charge the batteries in a relatively short period of time.

Next, in block 535, once balancing is determined to be required, and optionally when it is market beneficial to balance, the battery balancing and calibration protocol 500 takes the component of interest to a state to permit balancing. This state could be, for example, full charge or full discharge.

Finally, in block 545, once the component of interest is in a balanceable state, the battery balancing and calibration protocol 500 balances the SoC for the component of interest.

The battery balancing and calibration protocol 500 may coordinate these tasks, co-performing blocks 530 and 535 in order to both calibrate the components of interest in block 540 and balance the components of interest in block 545. Before balancing the component of interest, it may be beneficial to also calibrate the sub-components of the component of interest.

The battery balancing and calibration protocol 500 may also coordinate which components are taken to a state to permit calibration or balancing, such that not all components in the BESS 100 are taken to that state simultaneously, or such that only so many components to not affect electrical performance or revenue performance are taken to that state simultaneously.

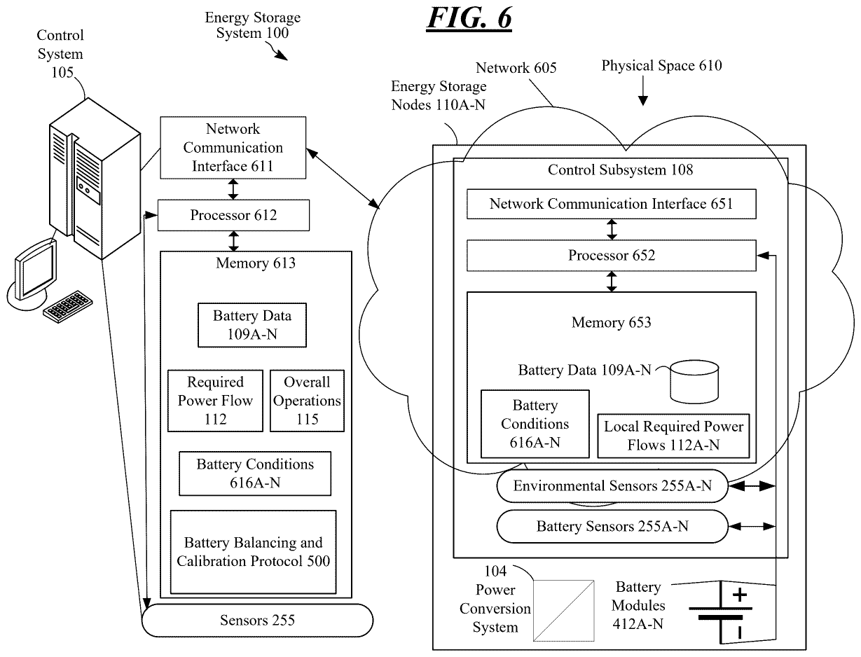

FIG. 6 is a high-level functional block diagram of the energy storage system of FIGS. 1A and 1B that depicts components of the control system 105 and the energy storage nodes 110A-N to control power flow 612, overall operations and implementation of the battery balancing and calibration protocol 500.

As shown, the plurality of energy storage nodes 110A-N include a battery storage element 111A-N, a power conversion system 104, and a control subsystem 108 to receive battery data 109A-N from the environmental and battery sensor 255, the battery storage element 111A-N, the power conversion system 104, or a combination thereof.

The control system 105, energy storage nodes 110A-N, external grid 113, and other components of the system 100 can be in communication over a network 605 or one or more networks 605A-N. The networks 605A-N can be a local area network, wide area network, or a combination thereof. For example, the control system 105 can be coupled via a local area network to the energy storage nodes 110A-N and the external grid 113. Alternative or additionally, the control system 105 can be coupled via a wide area network to the energy storage nodes 110A-N and external grid 113. Or the control system 105 can be coupled via a combination of networks, such as via a local area network to components of the energy storage system 100, including the energy storage nodes 110A-N, and coupled via a wide area network to the external grid 113.

Control system 105 includes a network communication interface 611 configured for wired or wireless communication over the network 605. The control system 105 further includes a memory 613, and a processor 612 coupled to the network communication interface 611 and the memory 613. As shown, the memory 613 of the control system 105 is configured to store battery data 109A-N, a required power flow 112, overall operations 115, and battery conditions 616. The control system 105 can also include sensors 255 coupled to the processor 612 to detect or monitor various system parameters, such as power, temperature, voltage, current, resistance, and/or impedance. For example, the sensors 255 can be coupled to the HV bus 251.

Control system 105 is configured to receive or store a required power flow 112 or an overall operations 115. The required power flow 112 can include an active power, a reactive power, or a total system power discharge or charge requirement. The required power flow 112 can be a power command for the external grid 113 based on a customer or independent system operator request received over the network 605 from the external grid 113, in which case the power command is externally determined.

The overall operations 115 can be a power command for the external grid 113 based on parameters in a customer or independent system operator request received over the network 605 from the external grid 113. The control system 105, control subsystem 108, or both can take the parameters of the overall operations 115 and attempt to best implement the overall operations 115. In this case, the power command to achieve the overall operations 115 is internally determined by the control system 105, for example, based on satisfying the customer or independent system operator request for the external grid 113.

Control system 105 can take the required power flow 112 needed for the external grid 103, for example, as requested by a customer or software application or required during the bid into market or otherwise change an operation of an asset to promote calibration or balancing, as discussed above in blocks 520 and 525 of FIG. 5.

Energy storage nodes 110A-N include a control subsystem 108, battery modules 412A-N, and a power conversion system 104. Control subsystem 110 of the energy storage nodes 110A-N includes a network communication interface 651 configured for wired or wireless communication over the network 605. The control subsystem 108 further includes a memory 653, and a processor 652 coupled to the network communication interface 651 and the memory 653. As shown, the memory 653 of the control subsystem 108 is configured to store battery data 109A-N, battery conditions 616A-N, and local required power flows 112A-N.

The control subsystem 108 further includes environmental sensors 255A-N and battery sensors 255A-N coupled to the processor 652. Environmental sensors 255A-N can measure, for example, humidity and temperature inside of an enclosure of the energy storage nodes 110A-N. Battery sensors 255A-N can include, for example, a voltage sensor, a current sensor, and a temperature sensor to measure readings of battery data 109A-N, such as a voltage, a current, a temperature, or other physical phenomena occurring within the battery modules 412A-N.

In addition to determining an implementation of the battery balancing and calibration protocol 500 (see, FIG. 5) for a component of interest within the energy storage system 100, the control subsystem 108 or the control system 105 may be further configured to determine at least one battery condition 116A-O about one or more of the energy storage nodes 110A-N from the battery data 109A-N. Battery conditions 616A-N can be algorithmically determined estimates from battery data 109A-N, readings from the sensors 255A-N that monitor various system parameters on, for example, the HV bus 251, or a combination thereof.

Some battery conditions 616A-N can be inputted by an operator of the energy storage system 101 into a software application on a separate computing device that is coupled to the control system 105 or the control subsystem 108 over the network 605, and used, for example to determine state of charge. Alternatively, a battery management system (BMS)or the control subsystem 108 can derive a state of charge from the measured raw data 599.

Each of the energy storage nodes 110A-N can include the power conversion system 104 for controlling the respective one of the local required power flows 112A-N. The battery data 109A-N can include a voltage, a current, a temperature, or other physical phenomena occurring within the battery module 412A, or a combination thereof.

The battery energy storage system 100, energy storage nodes 110A, power conversion system 104, and various controllers may rely on at least one processor 613, 652. The processor serves to perform various operations, for example, in accordance with instructions or programming modules executable by the processor. Although the processor may be configured by use of hardwired logic, typical processors are general processing circuits configured by execution of programming. The processor can include elements structured and arranged to perform one or more processing functions, typically various data processing functions. Although discrete logic components could be used, the examples utilize components forming a programmable CPU. The processor for example includes one or more integrated circuit (IC) chips incorporating the electronic elements to perform the functions of the CPU. The processor, for example, may be based on any known or available microprocessor architecture, such as a Reduced Instruction Set Computing (RISC) using an ARM architecture, as commonly used today in mobile devices and other portable electronic devices. Of course, other processor circuitry may be used to form the CPU or processor hardware. Although the described examples of the processor each focus on only one microprocessor, for convenience, a multi-processor architecture can also be used. A digital signal processor (DSP) or field-programmable gate array (FPGA) could be suitable replacements for the processor but may consume more power with added complexity. The processor may also partially or fully comprise (1) a single board computer used for local computation, processing, and control of the battery energy storage system 100, energy storage nodes 110A, power conversion system 104, and various controllers; (2) an application-specific integrated circuit used for local computation, processing, and control of the battery energy storage system 100, energy storage nodes 110A, power conversion system 104, and various controllers; (3) other known distributed control system elements; or (4) a combination thereof.

A memory 613, 653 can be coupled to the processor 612, 652. Memory devices are for storing data and programming. In the example, memory devices may include a flash memory (non-volatile or persistent storage) and/or a random-access memory (RAM) (volatile storage). The RAM serves as short term storage for instructions and data being handled by the processor e.g., as a working data processing memory. The flash memory typically provides longer term storage.

Of course, other storage devices or configurations may be added to or substituted for those in the example. Such other storage devices may be implemented using any type of storage medium having computer or processor readable instructions or programming stored therein and may include, for example, any or all of the tangible memory of the computers, processors or the like, or associated modules.

A network interface 611, 651 can be coupled to the processor. The network interfaces of the energy storage system 100, energy storage nodes 110A, power conversion system 104, and various controllers are configured to communicate with one another.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second, or evident and alternative, and the like may be used solely to distinguish one entity or action from another without necessarily requiring or implying any actual such relationship or order between such entities or actions. The terms “comprises,” “comprising,” “includes,” “including,” or any other variation thereof, are intended to cover a non-exclusive inclusion, such that a process, method, article, or apparatus that comprises or includes a list of elements or steps does not include only those elements or steps but may include other elements or steps not expressly listed or inherent to such process, method, article, or apparatus. An element preceded by “a” or “an” does not, without further constraints, preclude the existence of additional identical elements in the process, method, article, or apparatus that comprises the element.

In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, the subject matter to be protected lies in less than all features of any single disclosed example. Thus, the following claims are hereby incorporated into the Detailed Description, with each claim standing on its own as a separately claimed subject matter.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present concepts.

What is claimed:

1. An energy storage system, comprising:
a plurality of energy storage nodes, wherein each energy storage node includes a plurality of battery modules; and
a control system comprising at least one processor coupled to the plurality of energy storage nodes and a memory configured to receive or store data and programming, wherein the at least one processor is configured to:
perform operations in accordance with execution of the programming;
measure and record operational and environmental data of at least one component of interest within the energy storage system to provide raw data; and
determine an implementation of at least one of a battery balancing or calibration protocol of the control system for the at least one component of interest based upon an analysis of the measured raw data, wherein the implementation of the at least one battery balancing or calibration protocol is based on a predetermined value of at least one of the measured raw data, a time interval, or an amount of energy throughput for the component of interest, wherein:
when in the determination for the implementation of the at least one of the battery balancing or calibration protocol, the processor is further configured to:
compare a previously acquired value for a state of charge for the component of interest to values derived from at least one of the measured raw data, the time interval, or the amount of energy throughput to provide a calibration determination for a state of charge calibration, wherein when the calibration determination is a predetermined value, an operation state of the component of interest is switched to a state to implement a calibration, and the state of charge is calibrated to a desired level for the component of interest; and
compare the previously acquired value of the state of charge for a sub-component of the component of interest to values derived from at least one of the measured raw data, the time interval, or the amount of energy throughput to provide a balancing determination for a state of charge balancing, wherein when the balancing determination is a predetermined value, an operation state of the component of interest is switched to a state to implement a balancing, and the state of charge is balanced to a desired state.

2. The energy storage system of claim 1, further comprising a power conversion system (PCS) connected to the plurality of energy storage nodes and an external grid system including an energy source and a connected load, wherein the power conversion system is configured to convert bi-directionally between direct current (DC) and alternating current (AC) power.

3. The energy storage system of claim 1, wherein the plurality of energy storage nodes is arranged into a collection of nodes, each collection being paired with a distributed power conversion system to constitute a battery core.

4. The energy storage system of claim 1, further comprising at least one sensor arranged to measure and store the operational and environmental data in a memory accessible to the at least one processor of the control system.

5. The energy storage system of claim 4, wherein the at least one sensor is arranged to measure at least one of voltage, current, temperature or state of charge from the at least one component of interest of the energy storage system.

6. The energy storage system of claim 1, wherein the at least one battery balancing or calibration protocol is implemented across an entirety of the plurality of nodes of the energy storage system or a subset of components including multiple energy storage nodes.

7. The energy storage system of claim 1, wherein when the determination is to implement the at least one of the battery balancing or the calibration protocol, the processor is further configured to change an operation for the component of interest to permit the implementation, and to adjust an operation of a remainder of the energy storage system to calibrate for a time period of the implementation of the protocol for the at least one component.

8. The energy storage system of claim 1, wherein in the battery balancing, each component and subcomponent of the energy storage system is adjusted to have a same or approximately a same state of charge (SoC) for a given time.

9. A method, comprising:
measuring and recording operational and environmental data of at least one component of interest within an energy storage system to provide raw data; and
determining an implementation of at least one of a battery balancing or calibration protocol of a processor in a control system for the at least one component of interest based upon an analysis of the measured raw data, wherein the implementation of the at least one battery balancing or calibration protocol is based on a predetermined value of at least one of the measured raw data, a time interval, or an amount of energy throughput for the component of interest, wherein:
when in the determining for the implementation of the at least one battery balancing or calibration protocol, the processor further:
comparing a previously acquired value for a state of charge for the component of interest to values derived from at least one of the measured raw data, the time interval, or the amount of energy throughput to provide a calibration determination for a state of charge, wherein when the calibration determination is a predetermined value, switching an operation state of the component of interest to a state to implement a calibration, and calibrating the state of charge to a desired level for the component of interest; and
comparing the previously acquired value of the state of charge for a sub-component of the component of interest to values derived from at least one of the measured raw data, the time interval, or the amount of energy throughput to provide a balancing determination for a state of charge, wherein when the balancing determination is a predetermined value, switching an operation state of the component of interest to a state to implement a balancing, and balancing the state of charge to a desired state.

10. The method of claim 9, further comprising:
connecting a power conversion system (PCS) to the plurality of energy storage nodes and an external grid system including an energy source and a connected load;
wherein the power conversion system is configured to convert bi-directionally between direct current (DC) and alternating current (AC) power.

11. The method of claim 10, further comprising arranging the plurality of energy storage nodes into a collection of nodes, each collection being paired with a distributed power conversion system to constitute a battery core.

12. The method of claim 10, further comprising arranging at least one sensor to measure and store the operational and environmental data in a memory accessible to the at least one processor of the control system.

13. The method of claim 12, further comprising the at least one sensor measuring at least one of voltage, current, temperature or state of charge from the at least one component of interest of the energy storage system.

14. The method of claim 9, further comprising implementing the at least one battery balancing or calibration protocol across an entirety of the plurality of nodes of the energy storage system or a subset of components including multiple energy storage nodes.

15. The method of claim 9, wherein when implementing the at least one of the battery balancing or the calibration protocol, the processor further changing an operation for the component of interest to permit the implementation, and adjusting an operation of a remainder of the energy storage system to calibrate for a time period of the implementation of the protocol for the at least one component.

16. The method of claim 12, wherein in the battery balancing, each component and subcomponent of the energy storage system is adjusted to have a same or approximately a same state of charge (SoC) for a given time.

17. A non-transitory computer-readable medium, comprising a battery balancing and calibration module, wherein execution of the battery balancing and calibration module by one or more processors configures one or more computing devices to:
measure and record operational and environmental data of at least one component of interest within an energy storage system to provide raw data; and
determine an implementation of at least one of the battery balancing or calibration module of a control system for the at least one of the component of interest based upon an analysis of the measured raw data, wherein the implementation of the at least one battery balancing or calibration protocol is based on a predetermined value of at least one of the measured raw data, a time interval, or an amount of energy throughput for the component of interest, wherein:
when in the determination for the implementation of the at least one of the battery balancing or calibration protocol, the processor is further configured to:
compare a previously acquired value for a state of charge for the component of interest to values derived from at least one of the measured raw data, the time interval, or the amount of energy throughput to provide a calibration determination for a state of charge calibration, wherein when the calibration determination is a predetermined value, an operation state of the component of interest is switched to a state to implement a calibration, and the state of charge is calibrated to a desired level for the component of interest; and
compare the previously acquired value of the state of charge for a sub-component of the component of interest to values derived from at least one of the measured raw data, the time interval, or the amount of energy throughput to provide a balancing determination for a state of charge balancing, wherein when the balancing determination is a predetermined value, an operation state of the component of interest is switched to a state to implement a balancing, and the state of charge is balanced to a desired state.

18. The non-transitory computer-readable medium of claim 17, wherein the processor further implements the at least one battery balancing or calibration protocol across an entirety of the plurality of nodes of the energy storage system or a subset of components including multiple energy storage nodes.

19. The non-transitory computer-readable medium of claim 17, wherein when implementing the at least one of the battery balancing or the calibration protocol, the processor further changes an operation for the component of interest to permit the implementation, and adjusts an operation of a remainder of the energy storage system to calibrate for a time period of the implementation of the protocol for the at least one component.

20. The non-transitory computer-readable medium of claim 17, wherein in the battery balancing, the processor adjusts each component and subcomponent of the energy storage system to have a same or approximately a same state of charge (SoC) for a given time.
